(19) United States
(12) Patent Application Publication
(10) Pub. No.: US 2007/0069717 A1
(43) Pub. Date: Mar. 29, 2007

(54) Self-shielded electronic components

(76) Inventors: Tak Shun Cheung, Scarborough (CA); John Robert Long, Deift (NL)

Correspondence Address: TAROLLI, SUNDHEIM, COVELL & TUMMINO L.L.P., 1300 EAST NINTH STREET, SUITE 1700, CLEVEVLAND, OH, 44114, US

(21) Appl. No.: 11/237,343

(22) Filed: Sep. 28, 2005

(51) Int. Cl. G01R 31/28

(52) U.S. Cl. 324/158.1

(57) ABSTRACT

An electronic component including at least one first conductor for operating at a first voltage applied thereto and at least one second conductor for operating at a second voltage applied thereto. The second voltage is smaller than the first voltage and at least a portion of the second conductor is located on at least one side of the first conductor whereby the second conductor acts as a shield to substantially inhibit at least one of magnetic and electric field from passing from the first conductor to a surrounding medium.

### FIELD OF THE INVENTION

The present invention relates generally to electronic components. More particularly, the present invention relates to shielding of passive electronic components such as inductors, transformers and balun power combiners or balun power splitters. BACKGROUND OF THE INVENTION

Future broadband wireless networks will utilize integrated circuits that process radio frequency (RF) signals in bands where wavelengths may be just a few millimeters. For example, operation in the 24 GHz ISM band reduces congestion in lower frequency bands and supports data services up to hundreds of megabytes per second (Mb/s), enabling the next generation of wireless access and connectivity. Efficiency of passive electronic components is paramount when operating at radio frequencies. This is also true at millimeter wavelengths, because the quality of electronic circuit realizations depends more upon low-loss passive components as the wavelength shrinks.

Implementation of a 24 GHz power amplifier in silicon technology, for example, is hindered by transmission line effects that change the behavior of the signals being processed considerably. Signal attenuation ranges between 0.5 and 2.0 dB/mm on medium resistivity (100-5 Ω-cm) silicon substrates. In addition, gain-bandwidth and breakdown voltage limitations of active devices constrain both the output power and operating frequency. Thus, implementation of such an amplifier is limited to more expensive substrate materials than silicon IC technology.

Presently, most monolithic microwave integrated circuits (MMICs) are fabricated using compound semiconductor materials that are three to five times more expensive to manufacture than silicon, such as gallium arsenide (GaAs) and indium phosphide (InP). Such materials cause the final product to be priced out of range for many consumer electronic applications.

In prior art balun (i.e., balanced-to-unbalanced) power combiners, for example, power outputs from a pair of amplifiers are combined to provide a single output. Two amplifiers drive two sections of the primary conductor of the balun. FIG. 1A shows a simplified plan view of an exemplary prior art balun power combiner indicated generally by the numeral 20. In the balun power combiner 20 as shown, two differential amplifiers drive the primary conductor 26. Physical proximity of the primary and secondary conductors couples the magnetic field produced by current flow in either conductor. Therefore, an alternating current in the primary conductor 26 induces a current flow in the secondary conductor 24. FIG. 1B shows a sectional view along the line B-B of FIG. 1A. As shown FIG. 1B, the primary conductor 26 and secondary conductor 24 are implemented using the same metal wiring plane, or are co-planar, and above the silicon substrate 22 in the orientation as shown. However, such balun power combiners suffer several disadvantages.

First, because the conductors lie on the same level (i.e., they are coplanar), there is relatively little magnetic field coupling the conductors of the balun. This is caused by leakage of the magnetic flux produced by alternating current flowing in either conductor, which results in signal loss and attenuation. The magnetic coupling is quantified by the coupling coefficient, k, where k is approximately 0.6 to 0.7 for a typical implementation as shown in FIG. 1. Further, at high frequency, current crowds along the edges of the metal conductors of both the primary and secondary that are closest to each other. FIG. 1C is a sectional view similar to FIG. 1B, and further shows current crowding along edges of the primary conductor 26 and secondary conductor 24. Thus, in this example, current flows only along a single edge of the primary conductor that is adjacent to the single edge of the secondary conductor along which current flows. Although the conductors are constructed from relatively wide conductors (i.e., about 50 μm wide shown for the primary conductor in FIG. 1C), the current flows only along the surface of each conductor. This phenomenon is commonly referred to as the skin effect. Current crowding due to skin effect increases with increasing frequency, and results in Ohmic loss and attenuation of the RF signal.

Inductors are another example of electronic components employed in the realization of electronic circuits for wireless communications. Inductors provide a frequency dependent impedance for filters, RF chokes or resonators. A time-varying current flowing through the inductor induces an electromotive force that in turn opposes current flow in the inductor. FIG. 2 shows a simplified perspective view of a prior art spiral monolithic inductor fabricated in silicon semiconductor technology and indicated generally by the numeral 30. The inductor 30 is a layered structure including the conductor 32, followed by successive layers of an insulator, such as silicon dioxide 34, a silicon substrate 36 and finally a ground plane 38. Electrical connections to the conductor 32 include a first terminal 40 and a second terminal 42.

In use, a time-varying (AC) signal is applied to the first terminal 40 of the inductor 30 and the second terminal 42 is grounded. Normally, the inductor is used in the resonant condition in a circuit. The inductor voltage (V_{L}) is highest at the first terminal 40 and gradually diminishes toward the second terminal 42. The inductor current (I_{L}) is lowest at the first terminal 40 and increases gradually towards the second terminal 42. The ground connection provides a low impedance path for the current (I_{L}) to flow through, and therefore the current (I_{L}) is highest at the ground terminal.

When in use, energy is coupled from the conductor 32 to the surroundings, including the substrate. It is known that the energy dissipated by the substrate is proportional to the square of the line voltage and is therefore highest proximal to the first terminal 40 of the conductor 32. This energy loss attenuates the desired RF signal and reduces the efficiency of electronic circuits employing the inductor.

FIG. 3 shows a top view of a prior art symmetric inductor indicated generally by the numeral 44. The symmetric inductor 44 includes first and second terminals 46, 48, respectively, similar to the above-mentioned prior art inductor 30. A differential signal is applied to the symmetric inductor 44 such that the first and second terminals, 46, 48, respectively, are excited by AC signals that are 180° out of phase. A virtual ground 50 exists at the electrical center of the inductor 44. In the present example, the line voltage is lowest at the virtual ground 50 and increases toward the first and second terminals 46, 48, respectively. Also, the line current is lowest at the first and second terminals 46, 48, respectively, and increases towards the virtual ground 50. These conditions apply below the first self-resonant frequency of the inductor.

Similar to the first example of the inductor 30, energy is dissipated in the substrate. In this example, the energy dissipated at (parallel) resonance is highest at the first and second terminals 46, 48, and reduces the performance of the associated electronic circuitry.

In order to reduce electric field leakage to the substrate in on-chip components, for example, the use of a metal shield located between the conductors and the substrate and connected to an external ground has been suggested. Such electronic components suffer disadvantages, however. For example, the connections to the circuit ground have inductance and thus a voltage (i.e., potential) difference is introduced between the shield and the ground. Further, other circuitry components are added in series, thereby introducing parasitic elements in series.

Clearly the prior art electronic components suffer significant loss from the conductor (or portions thereof) to the lossy substrate, thereby reducing efficiency and performance.

### SUMMARY OF THE INVENTION

According to one aspect, there is provided an electronic component including at least one first conductor for operating at a first voltage applied thereto and at least one second conductor for operating at a second voltage applied thereto. The second voltage is smaller than the first voltage and at least a portion of the second conductor is located on at least one side of the first conductor whereby the second conductor acts as a shield to substantially inhibit at least one of magnetic and electric field from passing from the first conductor to a surrounding medium.

According to another aspect, there is provided a passive electronic component including at least two conductor portions. A first one of the conductor portions has a first voltage applied thereto, and a second one of the conductor portions has a second voltage applied thereto. The second voltage is smaller than the first voltage. The second one of the conductor portions is located adjacent at least one side of the first one of the conductor portions such that the second one of the conductor portions acts as a shield to substantially inhibit at least one of magnetic field and electric field from passing from the first one of the conductor portions to a surrounding medium.

Advantageously, the low-voltage conductor portion of the electronic component acts to shield the electric field from passing from the higher voltage conductor portion to a lossy surrounding, resulting in reduced energy loss. The portion of the conductor that acts as a shield can also be used for shielding electric field from passing from other conductors to the surroundings. In an alternative embodiment, the low-voltage conductor shields a second, higher-voltage conductor thereby reducing energy lost to the surroundings. Also, in the transformer according to an aspect of the present invention, magnetic coupling between the first and second conductors is increased as magnetic flux leakage is reduced, thereby decreasing signal attenuation. Further, efficiency of the electronic component is increased as current crowding causes the current to flow on edges of the first conductor that are closest to the second conductor. Because the first conductors are at least partially surrounded by the second conductors, current crowding causes the current to flow on all edges proximal the second conductors thereby increasing the surface area over which current flows and decreasing the Ohmic loss.

### BRIEF DESCRIPTION OF THE DRAWINGS

The present invention will be better understood with reference to the following description and to the drawings, in which:

FIGS. 1A to 1C show views of a balun power combiner of the prior art;

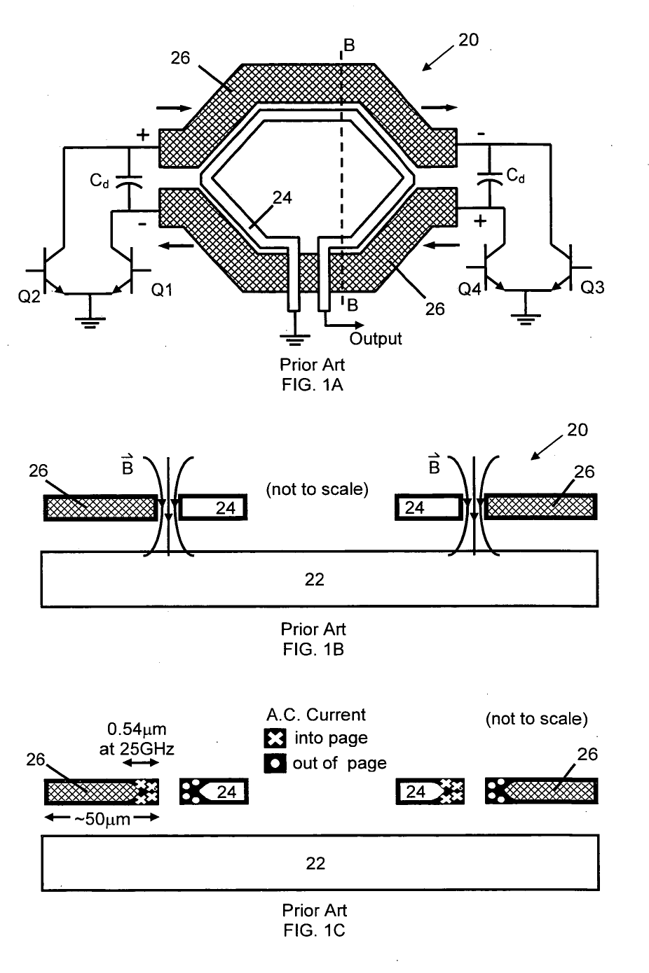

FIG. 2 shows a perspective view of a prior art spiral monolithic inductor;

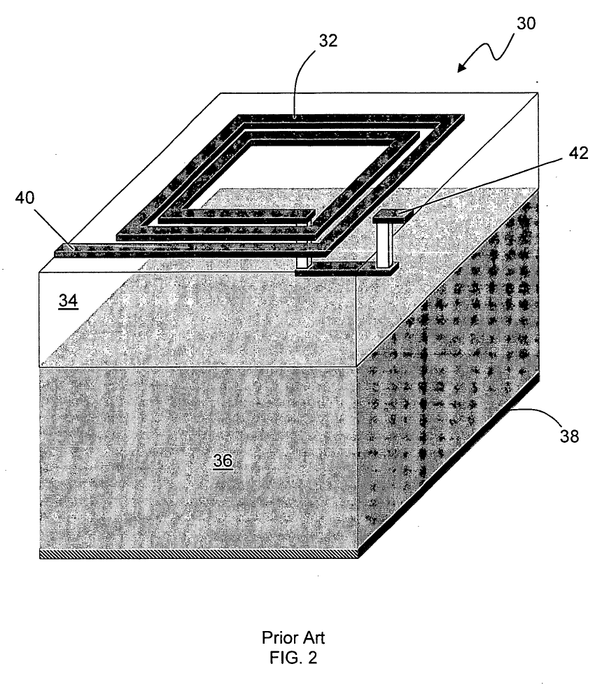

FIG. 3 shows a plan view of a prior art symmetrical inductor;

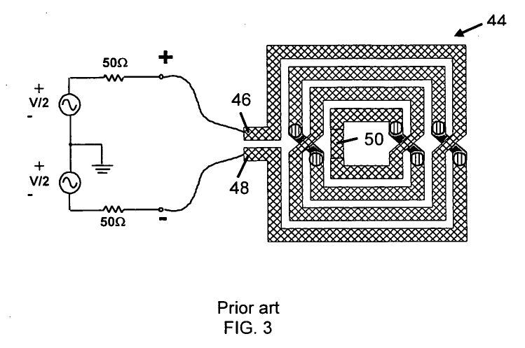

FIG. 4 shows a plan view of an electronic component according to one embodiment of the present invention;

FIG. 5 is a simplified schematic diagram of a power amplifier incorporating embodiments of the present invention;

FIGS. 6A and 6B show simplified plan views of an interstage transformer for interfacing stages in the power amplifier of FIG. 5, according to an embodiment of the present invention;

FIGS. 7A and 7B show simplified plan views of a balun for combining the output from two differential amplifiers into a single-ended output in the power amplifier of FIG. 5, according to another embodiment of the present invention;

FIGS. 8A and 8B show simplified plan views of a four-way power combiner for use in VLSI technology, according to another embodiment of the present invention;

FIG. 9A to 9C show simplified plan views of a self-shielded spiral inductor and components thereof, according to another embodiment of the present invention, FIG. 9A showing a plan view of the inductor, FIG. 9B showing a plan view of a conductor of the inductor of FIG. 9A and FIG. 9C showing a plan view of a shield of the inductor of FIG. 9A;

FIGS. 10A to 10C show simplified plan views of a self-shielded spiral inductor having top and bottom shields according to another embodiment of the present invention, FIG. 10A showing a top shield, FIG. 10B showing a conductor and FIG. 10C showing a bottom shield;

FIGS. 11A to 11C show simplified plan views of a symmetric self-shielded inductor according to another embodiment of the present invention, FIG. 11A showing a simplified plan view of the symmetric self-shielded inductor, FIG. 11B showing a plan view of a symmetric conductor of the symmetric self-shielded inductor of FIG. 11A, and FIG. 11C showing a plan view of a symmetric bottom shield of the symmetric self-shielded inductor of FIG. 11A;

FIG. 12 shows a bottom perspective view of a symmetric self-shielded inductor according to a yet another embodiment of the present invention; and

FIG. 13 shows a bottom perspective view of a symmetric self-shielded inductor according to still another embodiment of the present invention.

### DETAILED DESCRIPTION OF THE PREFERRED EMBODIMENTS

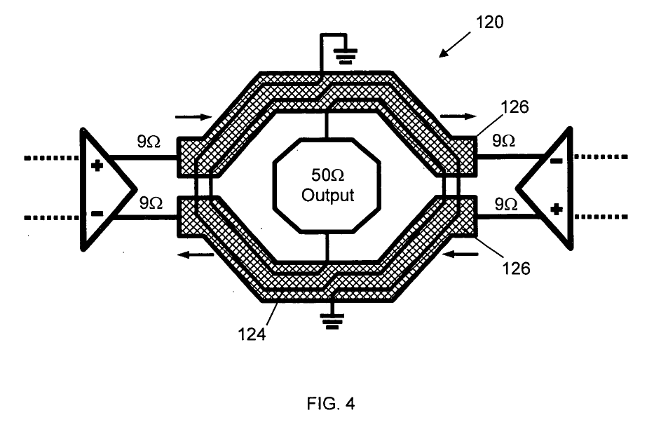

Reference is made to FIG. 4 to describe an electronic component 120 according to one embodiment of the present invention. The electronic component includes at least one first conductor 124 for operating at a first voltage applied thereto and at least one second conductor 126 for operating at a second voltage applied thereto. The second voltage is smaller than the first voltage and at least a portion of the second conductor 126 is located on at least one side of the first conductor 124 whereby the second conductor 126 acts as a shield to inhibit at least one of magnetic and electric field from passing from the first conductor 124 to a surrounding medium.

The following examples are provided to further illustrate various embodiments of the present invention. These examples are intended to be illustrative only and are not intended to limit the scope of the present invention.

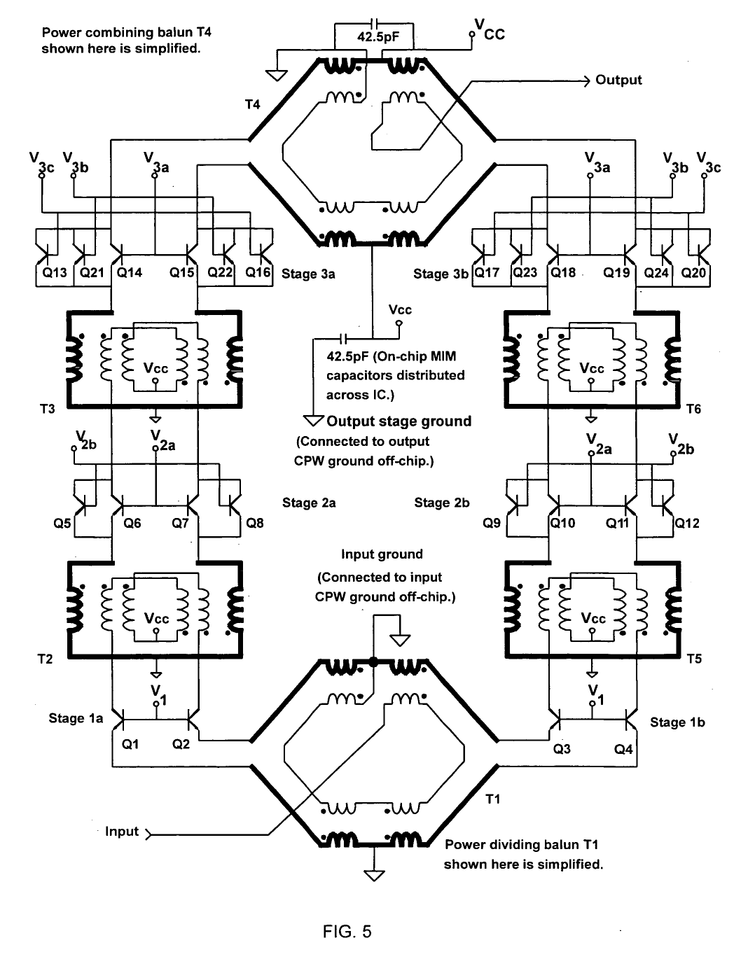

FIG. 5 is a simplified schematic diagram of a power amplifier incorporating embodiments of the present invention. The power amplifier includes 3 common-base amplifiers (stages 1 to 3), each pair of common-base amplifiers at a different stage in the power amplifier. An interstage transformer is used for impedance matching to interface between each stage. A power dividing balun splits the input signal into 2 paths which are then fed to each of the 2 input amplifier stages. A power combining balun sums the amplified signals and couples them to a 50 Ohm load at the output.

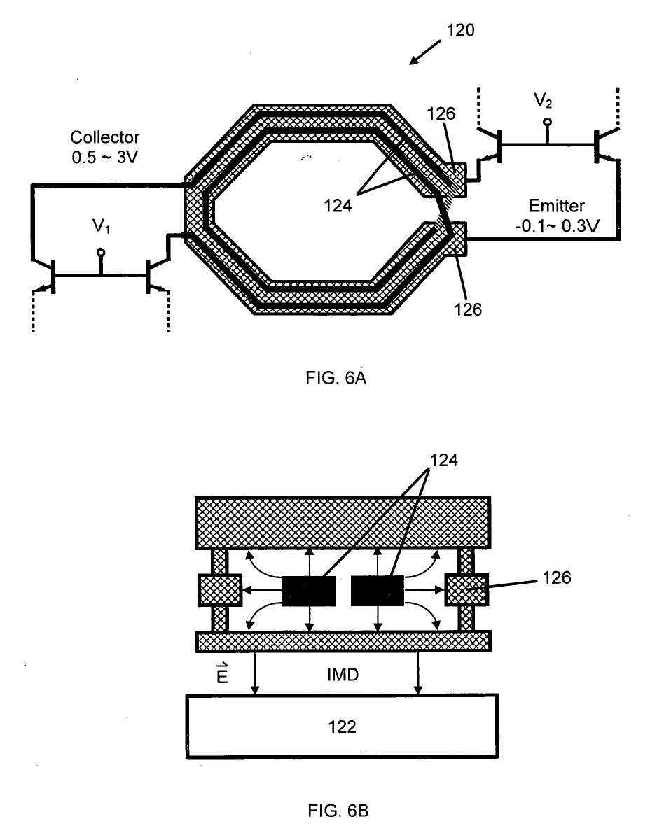

FIG. 6A shows a simplified plan view of the interstage transformer for interfacing stages in the power amplifier of FIG. 5, according to an embodiment of the present invention. The transformer is indicated generally by the numeral 120 and includes a first coil, referred to herein as the first conductor 124, and a second coil, referred to herein as the second conductor 126. As shown, the first conductor 124 is a 2-turn winding and is connected to the output (i.e., collector) side of the amplifying stage immediately prior to the interstage transformer 120. As a result of magnetic coupling, a current flows through the wider second conductor 126. The second conductor 126 is connected to the input (i.e., emitter) side of the amplifying stage immediately following the interstage transformer 120. The voltage in the first conductor 124 is much higher than the voltage in the second conductor 126. In the present exemplary embodiment, the voltage fluctuation at the collectors is from about 0.5 to about 3 Volts, resulting in a differential output voltage swing of about 2.5 Volts. The voltage fluctuation at the emitters is about −0.1 to about 0.3 Volts. Thus, the voltage difference at the emitter side is about 0.4 Volts. Clearly the voltage applied to the second conductor 126 is much smaller than the voltage at the first conductor 124.

The second conductor 126 is spaced from the substrate 122 (FIG. 6B) and has a much lower voltage than the first conductor 124. Thus, the second conductor 126 is used to form a shield by surrounding the first conductor 124, as shown in the sectional view of FIG. 6B, reducing magnetic field leakage and thereby improving magnetic field coupling between the first and second conductors 124, 126. In addition, the electric field emanating from the first conductor 124 is confined to a region above the underlying silicon substrate by the second conductor 126, thereby reducing the strength of the electric field entering the inter-metal dielectric (IMD) and silicon substrate 122 underlying the second conductor 126.

Current crowding due to the skin effect causes the current to flow mainly along the edges of the first conductor 124 that are closest to the second conductor 126. As shown in FIG. 6B, three edges of the first conductor 124 are approximately equally spaced from the second conductor 126. Thus, the current crowds along all three edges of the first conductor 124 that are closest to the second conductor 126.

Referring again to FIG. 5, the power amplifier also includes a power combining balun for combining the balanced (or differential) output from two differential amplifiers into a single-ended output.

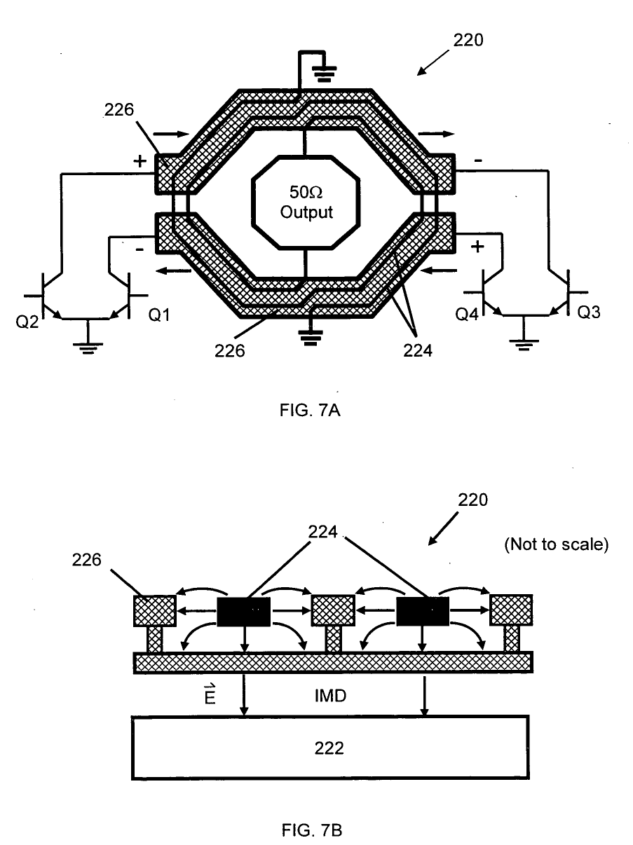

FIG. 7A shows a simplified plan view of the balun for combining the output from two differential amplifiers into a single-ended output in the power amplifier of FIG. 5, according to another embodiment of the present invention. The present embodiment includes many similar features to those of FIG. 6A, and the reference numerals used in FIG. 7A are raised by 100 to denote similar features of the present embodiment. The balun power combiner is indicated generally by the numeral 220 and includes a first conductor 224 and second conductor 226. The second conductor 226 includes two portions that are connected to the outputs of the final common base amplifier stages of FIG. 5. In the balun power combiner 220, the second conductor 226 is physically wider than and operates at lower voltage than the first conductor 224.

As a result of magnetic field coupling between the first and second conductors 224, 226, current flows through the relatively narrow first conductor 224, which provides the output for the power amplifier of FIG. 5. The voltage in the first conductor 224 is much higher than the voltage in the second conductor 226. Because it is disposed between the first conductor 224 and the underlying substrate, the second conductor 226 forms a shield by surrounding three sides of each turn of the first conductor 224, as best shown in FIG. 7B. Thus, the electric field from the first conductor 224 is confined by the second conductor 226, thereby inhibiting the electric field from traveling into the silicon-based substrate 222 (underlying inter-metal dielectric, or IMD, and silicon layers). This also reduces magnetic field leakage, thereby improving magnetic field coupling between first and second conductors 224, 226.

Current crowding caused by the skin effect forces the current to flow on edges of the first conductor 224 that are closest to the second conductor 226. As shown in FIG. 7B, the three edges of each turn of the first conductor 224 are approximately equally spaced from the second conductor 226. Thus, the current crowds to all three edges of the first conductor 224 that are closest to the second conductor 226.

In the present exemplary embodiment, the second conductor 226 acts as a shield. Thus, the second conductor 226 of the present embodiment performs a similar function to that performed by the second conductor 126 of the first described exemplary embodiment, which is to act as a shield for the other conductor or conductors.

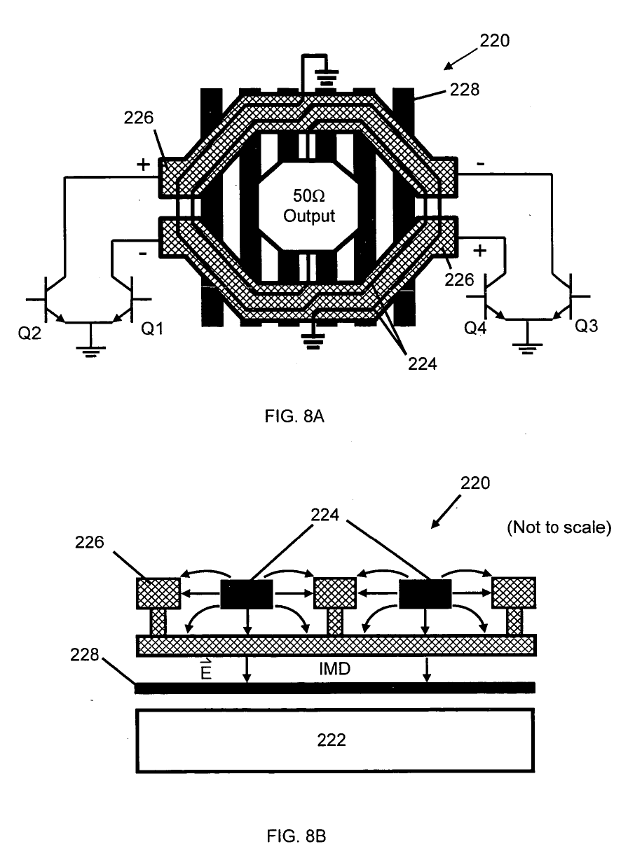

FIG. 8A shows a simplified plan view of a four-way power combiner for use in VLSI technology, according to another embodiment of the present invention. The present embodiment is similar to the embodiment shown in FIG. 7A and accordingly, like reference numerals are used to denote like parts. According to the present embodiment, the low impedance (0 Ω to 12.5 Ω) second conductor 226 is used to shield the higher voltage first conductor 224 (with impedance 0 Ω to 50 Ω) from the substrate 222 to reduce electric field leakage. Referring to FIG. 8B, the top layer of metal is about 4 μm thick, while the second metal layer (the layer of metal forming the second conductor 226 that is located between the first conductor 224 and the substrate 222) is about 1.25 μm thick. The spacing between the second conductor 226 and the first conductor 224 is about 5 μm.

In the present embodiment, a further metal layer 228 is located between the primary conductor 226 and the substrate 222. The further metal layer 228 includes a plurality of spaced apart, substantially parallel floating metal strips, as disclosed in the applicants own U.S. patent application Ser. No. 10/425,414, filed Apr. 29, 2003 and published under United States patent publication number 20040155728 on Aug. 12, 2004, the entire contents of which are incorporated herein by reference. These metal strips are tightly spaced such that electric field is further inhibited from passing through to the underlying substrate layer. The spacing between the strips is about equal to the minimum dimension (width) of the metal strips (about 1.0 μm).

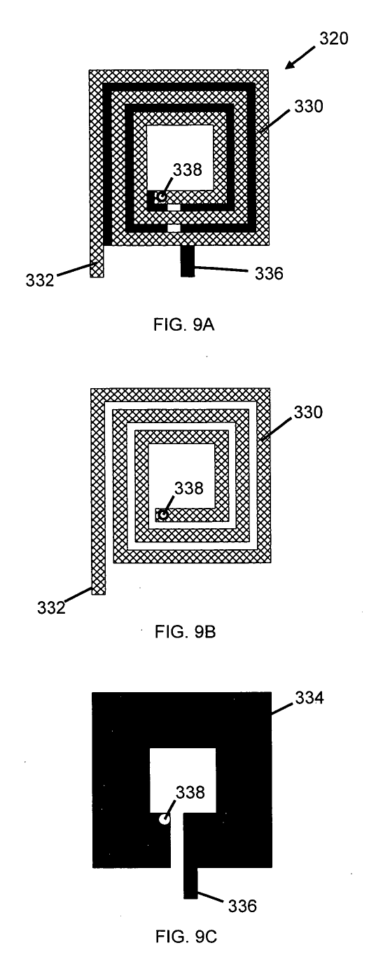

Reference is now made to FIGS. 9A to 9C to describe a self-shielded inductor according to another embodiment of the present invention. The shielded inductor 320 includes a conductor 330 with a first terminal 332 at an end thereof, to which a time-varying voltage is applied. The conductor 330 is connected to a second metal layer in the form of a conductor 334 that acts to shield electric field from the first conductor 330 to the surroundings. A time-varying voltage that is opposite in polarity and much lower in amplitude to that applied to the first terminal 332, is applied to an end terminal of the second conductor 334 (referred to herein as the second terminal 336). The application of a lower amplitude time-varying voltage that is opposite in polarity to the second terminal 336 results in a portion of the conductor 334 being at or close to zero potential (zero potential for static or time-varying voltage) on the second conductor 334, thereby providing the shield.

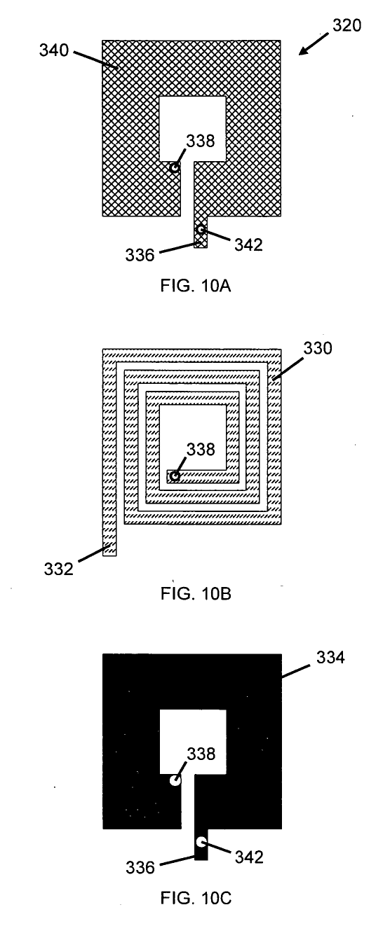

Referring now to FIGS. 10A-10C, a shielded inductor 320 according to another embodiment is shown. The shielded inductor 320 is similar to that shown in FIGS. 9A to 9C and includes a further metal layer in the form of another conductor 340. The conductor 340 is similar to the conductor 334 and is also attached to the conductor 330 by the via 338. The conductors 334, 340 are also connected by a second via 342, proximal the second terminal 336. Thus, in the present embodiment, the conductors 334, 340 each include a portion at or close to zero potential, thereby providing a pair of shields, one above the conductor 330 and one below the conductor 330.

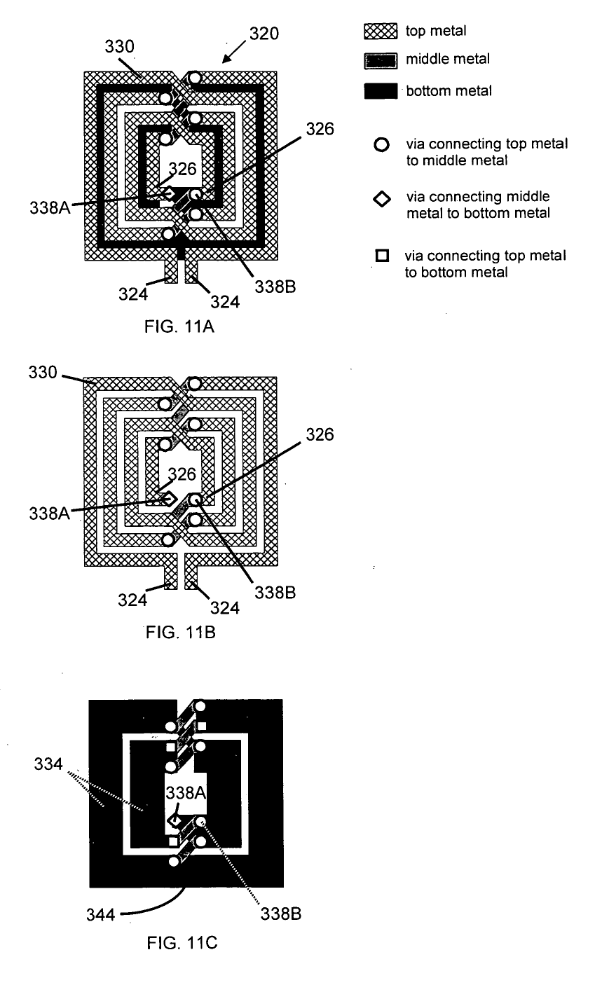

Referring now to FIGS. 11A to 11C a shielded inductor 320 according to another embodiment is shown. The present embodiment includes a symmetrical conductor 330 including a pair of differentially driven terminals resulting in a low-voltage portion 326 where the time-varying voltage is less than that in the remainder 324 (higher voltage portion) of the conductor 330. The shielded inductor 320 also includes a metal layer 334, or shield, attached to the symmetrical conductor 330 proximal the low-voltage portions 326. The metal layer 334 is connected by the first via 338A and a second via 338B to the conductor 330 and includes a point of zero potential or virtual ground 344. In the present embodiment, the low voltage portions 326 are similar to the low-voltage portion of the previously described shielded inductors. Thus the metal layer 334 with the virtual ground 344 shields the symmetrical conductor 330 in a similar manner to the previously described embodiments.

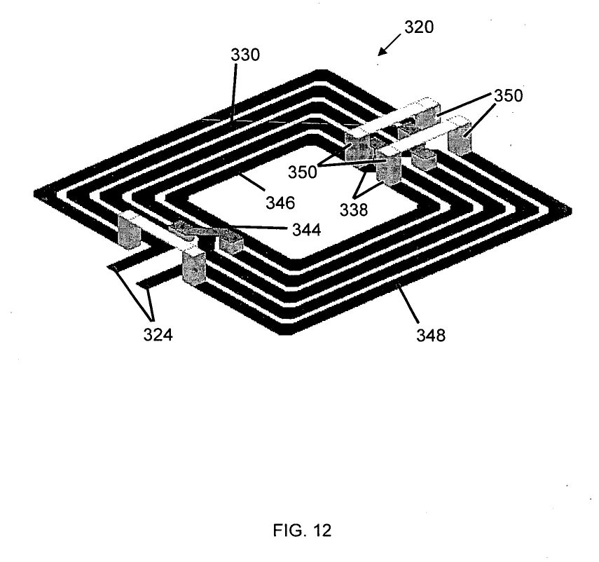

FIG. 12 is a bottom perspective view of a shielded inductor 320 according to still another embodiment of the present invention. The shielded inductor 320 includes a symmetrical conductor 330. In this embodiment, the symmetrical conductor 330 is shielded along an inside turn and along an outside turn in the same plane as the symmetrical conductor 330. An inner metal turn 346 is coplanar to, spaced from and extends around the inside of the symmetrical conductor 330. The inner metal turn 346 is connected as a continuation of the symmetrical conductor 330 using crossover via 338 and includes a virtual ground 344.

Similarly, an outer metal turn 348 is coplanar to, spaced from and extends around the outside of the symmetrical conductor 330. The outer metal turn 348 is connected to the inner metal turn 346 by further vias and interconnect layers 350. Thus both the inner metal turn 346 and the outer metal turn 348 effectively shield the inner side and outer side, respectively, of the symmetrical conductor 330.

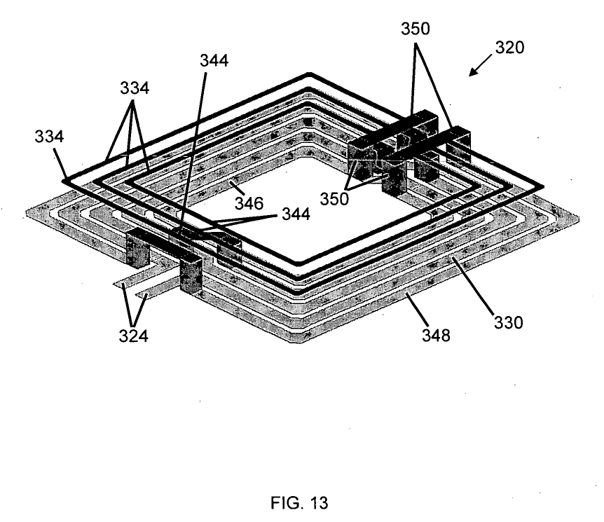

FIG. 13 is a bottom perspective view of a shielded inductor 320 according to yet another embodiment of the present invention. The shielded inductor 320 of the present embodiment is similar to the embodiment described with reference to FIG. 12 and further includes a metal layer 334 that acts as a shield between the conductor 320 and the substrate (not shown). The metal layer 334 of the present embodiment is made of narrow metal conductor rather than a solid plate. The metal shield conductors are attached to the vias and interconnect layers 350 and are therefore routed in parallel with the inner and outer metal turns 346 and 348, respectively. In the present embodiment, the metal shield conductors 334 include the virtual ground 344. Thus the conductors 334 reduce the electric field emanating into the substrate and the current induced in the substrate is reduced.

While the embodiments described herein are directed to particular implementations of the present invention, it will be understood that modifications and variations to these embodiments are within the scope and sphere of the present invention. For example, the size and shape of many of the features can vary while still performing the same function. The present invention is not limited to electronic components fabricated on silicon-based (silicon plus inter-metal dielectrics) substrates, as other substrates can be used. Also, the invention is not limited to, for example, a four-way power combining balun or the inductors shown and described as other baluns and transformer and inductor configurations are possible, such as eight-way power combining baluns, or step-up/step-down transformers. Those skilled in the art may conceive of still other variations, all of which are believed to be within the sphere and scope of the present invention.

What is claimed is:

1. An electronic component comprising:
at least one first conductor for operating at a first voltage applied thereto;
at least one second conductor for operating at a second voltage applied thereto, said second voltage being smaller than said first voltage, at least a portion of said second conductor is located on at least one side of said first conductor,
whereby said second conductor acts as a shield to substantially inhibit at least one of magnetic and electric field from passing from said first conductor to a surrounding medium.

2. The electronic component according to claim 1, wherein said at least one first conductor is surrounded on more than one side by said second conductor.

3. The electronic component according to claim 1, wherein said at least one first conductor is surrounded on all sides by said second conductor.

4. The electronic component according to claim 1, wherein said at least one first conductor comprises a pair of co-planar first conductors, and said second conductor surrounds said pair of co-planar first conductors.

5. The electronic component according to claim 1, wherein said at least one first conductor comprises a plurality of first conductors.

6. The electronic component according to claim 5, wherein said second conductor surrounds more than one side of each of said first conductors.

7. The electronic component according to claim 5, wherein said second conductor surrounds all sides of said plurality of first conductors.

8. The electronic component according to claim 1, further comprising a plurality of substantially parallel metal strips disposed between said second conductor and said substrate for further shielding electric field from passing through to the surrounding medium.

9. The electronic component according to claim 1, wherein said at least one second conductor comprises a plurality of second conductors.

10. A passive electronic component comprising:
at least two conductor portions, a first one of said conductor portions having a first voltage applied thereto, and a second one of said conductor portions having a second voltage applied thereto, the second voltage being smaller than the first voltage , the second one of said conductor portions located adjacent at least one side of said first one of said conductor portions such that the second one of the conductor portions acts as a shield to substantially inhibit at least one of magnetic field and electric field from passing from the first one of the conductor portions to a surrounding medium.

11. The electronic component according to claim 10, wherein said first one of said conductor portions is surrounded on more than one side by said second one of said conductor portions.

12. The electronic component according to claim 10, wherein said first one of said conductor portions is surrounded on all sides by said second one of said conductive conductor portions.

13. The electronic component according to claim 10, wherein said at least two conductor portions comprise a single inductor.

14. The electronic component according to claim 10, further comprising a substrate and wherein said second one of the conductor portions acts as a shield to inhibit at least one of magnetic and electric fields from passing from the first one of the conductive conductor portions to the substrate.

15. The electronic component according to claim 10, wherein said first one of said conductor portions comprises a first conductor and said second one of said conductor portions comprises a second conductor.

16. The electronic component according to claim 10, wherein said electronic component further comprises a substrate and wherein second one of said conductor portions is located between said first one of said conductor portions and the substrate.

17. The electronic component according to claim 10, wherein said second one of said conductor portions at least partially surrounds said first one of said conductor portions on more than one side.

18. The electronic component according to claim 10, wherein said second one of said conductor portions surrounds said first one of said conductor portions.

19. The electronic component according to claim 10, wherein said second one of said conductive conductor portions includes at least one turn connected to said first one of said conductive conductor portion.

20. The electronic component according to claim 10, wherein said second one of said conductor portions comprises a plurality of conductors.
